(19) United States
(12) Patent Application Publication
(10) Pub. No.: US 2013/0213705 A1
(43) Pub. Date: Aug. 22, 2013

(54) METHOD OF FABRICATING PRINTED-WIRING BOARD, AND PRINTED-WIRING BOARD

(71) Applicant: FUJITSU LIMITED, (US)

(72) Inventors: Mitsuo SUEHIRO, Kawasaki (JP); Tsuyoshi YAMAMOTO, Kawasaki (JP)

(73) Assignee: FUJITSU LIMITED, Kawasaki-shi (JP)

(21) Appl. No.: 13/756,898

(22) Filed: Feb. 1, 2013

(30) Foreign Application Priority Data
Feb. 21, 2012 (JP) 2012-034896

(51) Int. Cl. H05K 1/02; H05K 3/34; H05K 3/00

(52) U.S. Cl. CPC H05K 1/0296; H05K 3/0044; H05K 3/341
USPC 174/262; 29/829; 29/840; 174/260; 174/266

(57) ABSTRACT

A method of fabricating a printed-wiring board, includes: forming a through-hole across a thickness of a printed-wiring board, the forming of the through-hole including forming a first opening part having a first diameter, forming a second opening part having a second diameter, and forming a third opening part provided between the first opening part and the second opening part, wherein the second diameter is larger than the first diameter, and the third opening part is formed in a tapered shape whose diameter decreases toward the first opening part from the second opening part.

### CROSS-REFERENCE TO RELATED APPLICATION(S)

This application is based upon and claims the benefit of priority of the prior Japanese Patent Application No. 2012-034896, filed on Feb. 21, 2012, the entire contents of which are incorporated herein by reference.

### FIELD

The embodiment discussed herein is related to a method of fabricating a printed-wiring board, and the printed-wiring board.

### BACKGROUND

Currently, in order to solder an electronic component to a printed-wiring board, a process called “flow (or dip) solder mounting” is performed. This process is accomplished by inserting a lead pin of an electronic component into a through-hole of a printed-wiring board, and then dipping the lower surface of the printed-wiring board into a molten solder bath. Moreover, there is another process called “reflow solder mounting.” In this process, solder paste is applied to the interior of a through-hole in a printed-wiring board by printing the solder paste on the printed-wiring board; then the printed-wiring board is subjected to a reflow treatment while a lead pin of an electronic component is inserted into the through-hole.

Japanese Laid-open Patent Publication Nos. 04-137794 and 2003-78233 are examples of related art, in particular, the above-described techniques.

FIG. 20 is an explanatory view illustrating a printed-wiring board 91 in which a lead pin 95 of an electronic component 94 is inserted into and soldered to a through-hole 93 by means of flow solder mounting. As illustrated in FIG. 20, when the printed-wiring board 91 is thick, there are cases where molten solder 92 does not flow upward in the through-hole 93 adequately. As a result, the interior of the through-hole 93 may not be entirely filled with the molten solder 92.

FIG. 21 is an explanatory view illustrating the printed-wiring board 91 that has been subjected to reflow solder mounting. As illustrated in FIG. 21, when the printed-wiring board 91 is thick, there are cases where some of the solder paste is not successfully applied to the interior of the through-hole 93.

As a result, the interior of the through-hole 93 may not be entirely filled with solder 96 after a reflow treatment. In order to avoid a situation where there is an insufficient amount of the solder 96 in the through-hole 93, an increased amount of solder paste is applied to the interior of the through-hole 93.

However, when the thickness of the printed-wiring board 91 is significantly increased, even if solder paste is applied more liberally, the solder paste may simply spread over the area surrounding the through-hole 93, without entering the through-hole 93. In this case, as illustrated in FIG. 22, a land 97 formed in the surrounding area of the through-hole 93 is pulled upward due to the aggregation stress of the solder 96 contained in the solder paste which is caused by the reflow treatment. Finally, the land 97 may come off the surface of the printed-wiring board 91.

### SUMMARY

According to an aspect of the invention, a method of fabricating a printed-wiring board, includes: forming a through-hole across a thickness of a printed-wiring board, the forming of the through-hole including forming a first opening part having a first diameter, forming a second opening part having a second diameter, and forming a third opening part provided between the first opening part and the second opening part, wherein the second diameter is larger than the first diameter, and the third opening part is formed in a tapered shape whose diameter decreases toward the first opening part from the second opening part.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a view illustrating a cross section of a printed-wiring board according to an embodiment;

FIG. 2 is an explanatory view of a process in which a spot facing portion is formed in the printed-wiring board;

FIG. 3 is an explanatory view of a process in which a first opening part is formed in the printed-wiring board;

FIG. 4 is an explanatory view of a process in which a spot facing portion and a first opening part are formed in the printed-wiring board;

FIG. 5 is an explanatory view of a process in which respective plating resist materials are formed on first and second surfaces of the printed-wiring board;

FIG. 6 is an explanatory view of a process in which a plating layer is formed on the interior (or inner wall) of a through-hole in the printed-wiring board and a land is formed on the first surface of the printed-wiring board;

FIG. 7 is an explanatory view of a process in which respective solder resists are formed on the first and second surfaces of the printed-wiring board;

FIG. 8 is an explanatory view of a process in which solder paste is applied to the interior of the through-hole in the printed-wiring board from a side of the second surface;

FIG. 9 is an explanatory view of a process in which an electronic component is mounted on the second surface of the printed-wiring board;

FIG. 10 is an explanatory view of a process in which the printed-wiring board is subjected to a reflow (or heating) treatment;

FIG. 11 is an explanatory view of a process in which a solder ring is set in the through-hole of the printed-wiring board;

FIG. 12 is an explanatory view of a process in which solder paste is applied to the interior of the through-hole in the printed-wiring board from the side of the second surface;

FIG. 13 is an explanatory view of a process in which an electronic component is mounted on the second surface of the printed-wiring board;

FIG. 14 is an explanatory view of a process in which the printed-wiring board is subjected to a reflow (or heating) treatment;

FIG. 15 is a view illustrating a cross section of a printed-wiring board according to a comparative example;

FIG. 16 is a view illustrating a cross section of the printed-wiring board according to the comparative example in which adjacent through-holes are arranged at a short pitch;

FIG. 17 is a view illustrating a cross section of the printed-wiring board according to the embodiment in which adjacent through-holes are arranged at a short pitch;

FIG. 18 is a view illustrating a side of an electronic component;

FIG. 19 is a view illustrating a cross section of a printed-wiring board according to a modification;

FIG. 20 is a view illustrating a cross section of a printed-wiring board in which molten solder is not entirely filled in the through-hole after flow solder mounting;

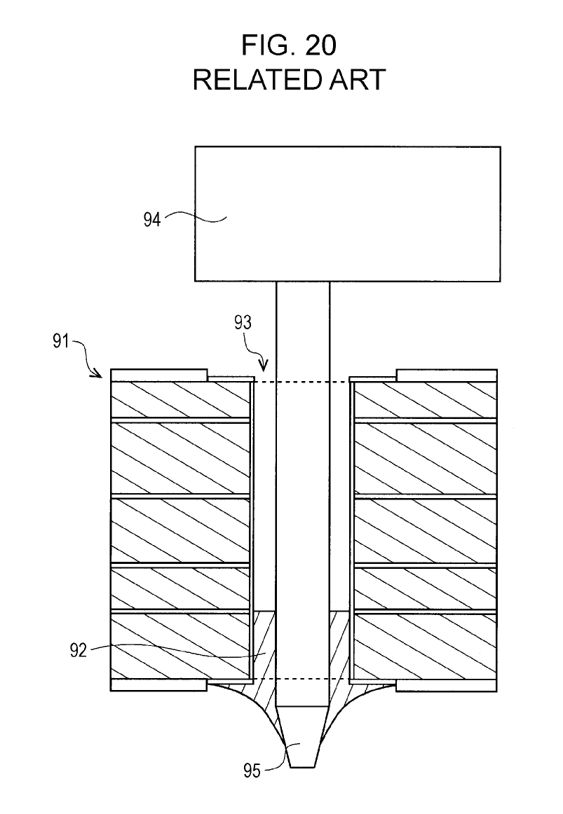

FIG. 21 is a view illustrating a cross section of a printed-wiring board in which molten solder is not entirely filled in the through-hole after reflow solder mounting; and

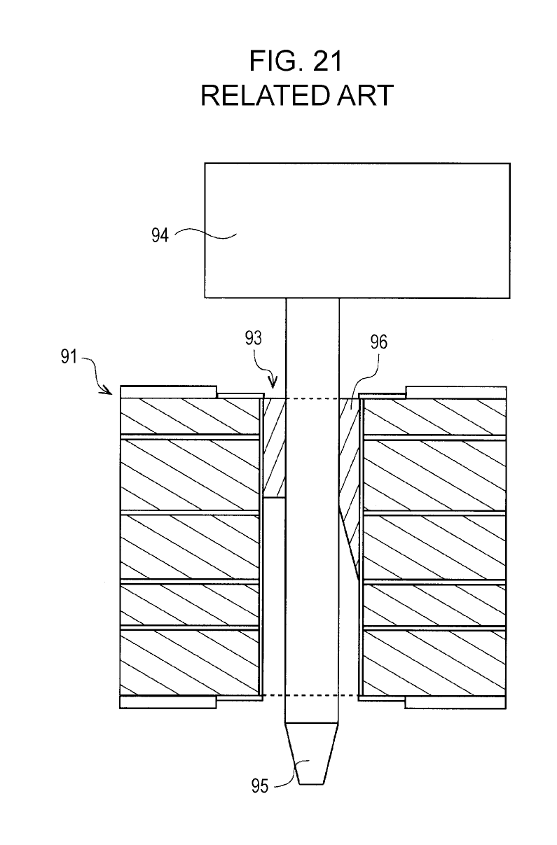

FIG. 22 is a view illustrating a cross section of a printed-wiring board in which a land formed in a surrounding area of the through-hole is pulled upward and comes off the surface during reflow solder mounting.

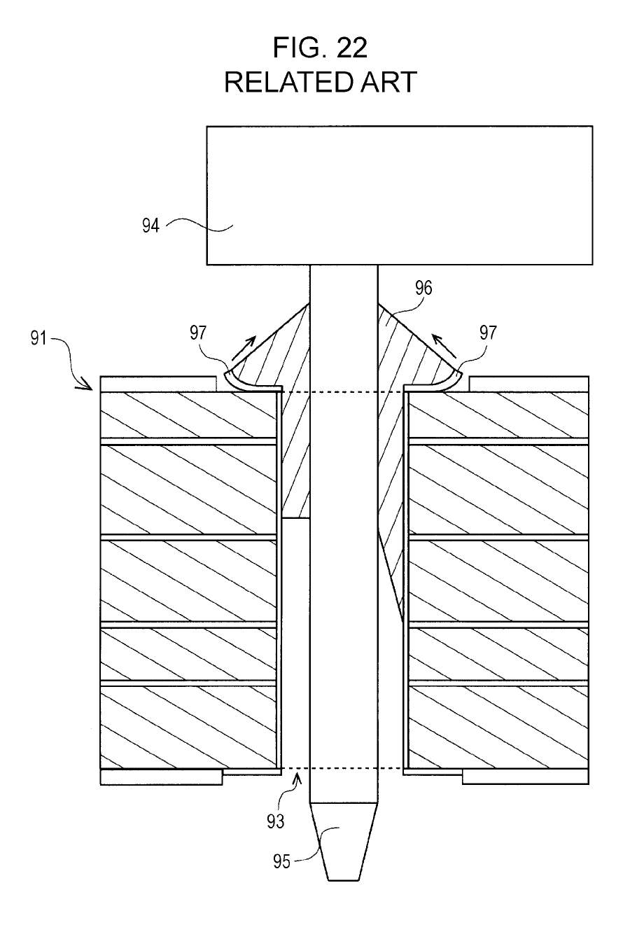

### DESCRIPTION OF EMBODIMENT

Hereinafter, a description will be given of a printed-wiring board according to an embodiment and a method of fabricating the printed-wiring board (or a method of mounting a component on the printed-wiring board), with reference to the accompanying drawings. Note that an exemplary configuration that will be described below is simply an example, and is not intended to limit an embodiment.

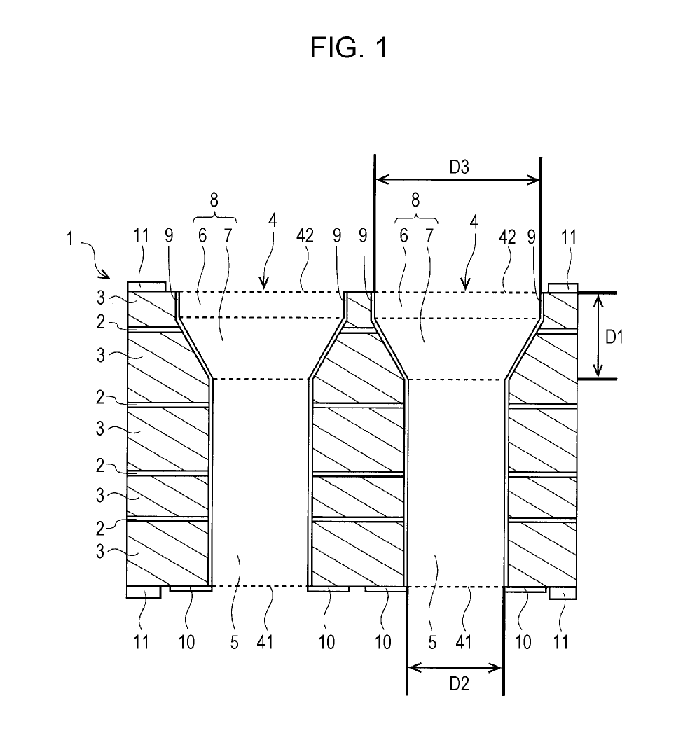

FIG. 1 is a view illustrating a cross section of a printed-wiring board 1 according to an embodiment. The printed-wiring board 1 includes a plurality of core resin layers 2 and a plurality of insulating layers 3 stacked on both surfaces of the core resin layers 2. The core resin layers 2 and the insulating layers 3 are made of, for example, epoxy resin.

The printed-wiring board 1 is provided with a plurality of through-holes 4. The through-holes 4 are formed so as to pass through the printed-wiring board 1. Each through-hole 4 has a first end with an aperture 41 and a second end with an aperture 42, and the apertures 41 and 42 are provided on a first surface (lower surface) and a second surface (upper surface), respectively, of the printed-wiring board 1. Each through-hole 4 includes a first opening part 5 and a spot facing portion 8 composed of a second opening part 6 and a third opening part 7. The first opening part 5 and the spot facing portion 8 communicate with each other. The third opening part 7 is provided between the first opening part 5 and the second opening part 6.

The depth of the spot facing portion 8 (indicated by an arrow D1 in FIG. 1) is, for example, 0.4 mm, but there is no limitation on the depth of the spot facing portion 8. The diameter of the second opening part 6 is larger than that of the first opening part 5. The diameter of the first opening part 5 (indicated by an arrow D2 in FIG. 1) is, for example, 0.7 mm. However, the first opening part 5 may have any diameter as long as it is smaller than the diameter of the second opening part 6. The diameter of the second opening part 6 (indicated by an arrow D3 in FIG. 1) is, for example, 1.42 mm. However, the second opening part 6 may have any diameter as long as it is larger than the diameter of the first opening part 5.

The third opening part 7 is formed in a tapered shape whose diameter gradually decreases toward the first opening part 5 from the second opening part 6. The first opening part 5 has a first aperture (one aperture) provided on the first surface (lower surface) of the printed-wiring board 1 and a second aperture (the other aperture) communicating with a first aperture (one aperture) of the third opening part 7. The second opening part 6 has a first aperture (one aperture) provided on the second surface (upper surface) of the printed-wiring board 1, and a second aperture (the other aperture) communicating with a second aperture (the other aperture) of the third opening part 7. Accordingly, the second aperture of the third opening part 7 which communicates with the first aperture of the second opening part 6 has a larger diameter than the first aperture of the third opening part 7 which communicates with the second aperture of the first opening part 5.

Each through-hole 4 has a plating layer 9 formed on an interior (or an inner wall) thereof. The plating layer 9 is made of, for example, copper (Cu). Furthermore, the printed-wiring board 1 has a plurality of lands 10 formed on the first surface (lower surface). In more detail, the lands 10 are formed around corresponding apertures 41 at the first ends of the through-holes 4. In other words, the lands 10 are formed around corresponding first apertures of the first opening parts 5. The lands 10 are made of, for example, copper (Cu).

Each of the first surface (lower surface) and the second surface (upper surface) of the printed-wiring board 1 has a solder resist 11 formed thereon. A solder resist 11 is formed around the lands 10 on the first surface (lower surface) of the printed-wiring board 1. Another solder resist 11 is formed around the apertures 42 at the second ends of the through-holes 4 on the second surface (upper surface) of the printed-wiring board 1. Each solder resist 11 is made of, for example, a thermosetting resin, such as an epoxy resin.

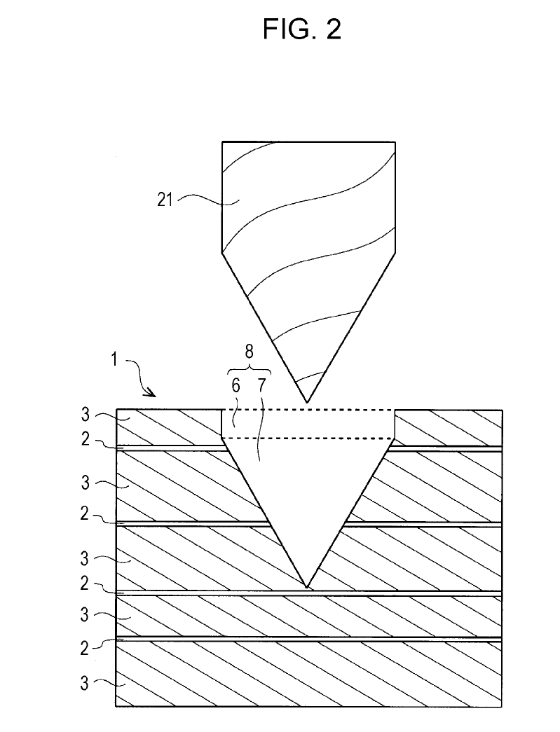

Next, a description will be given of a method of forming a through-hole 4 in the printed-wiring board 1 of FIG. 1, with reference to FIGS. 2 to 7. First, as illustrated in FIG. 2, the spot facing portion 8 is formed in the printed-wiring board 1 by using a first drill (mechanical drill) 21. In more detail, the first drill 21 drills into the second surface (upper surface) of the printed-wiring board 1 by a predetermined depth with the tip of the first drill 21 oriented toward the second surface (upper surface) of the printed-wiring board 1. As a result, the spot facing portion 8 is formed in the printed-wiring board 1.

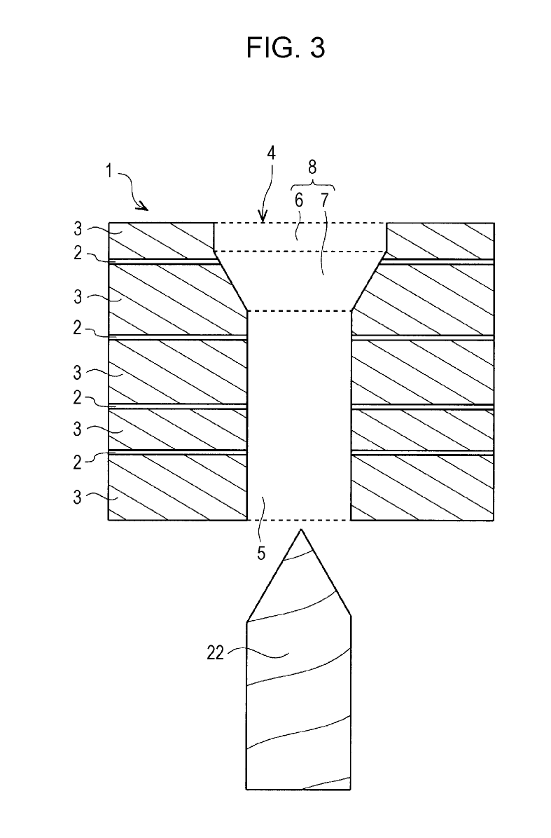

Then, as illustrated in FIG. 3, the first opening part 5 is formed in the printed-wiring board 1 by using a second drill (mechanical drill) 22. In more detail, the second drill 22 drills into the first surface (lower surface) of the printed-wiring board 1 by a predetermined depth with the tip of the second drill 22 oriented toward the first surface (lower surface) of the printed-wiring board 1. As a result, the first opening part 5 is formed in the printed-wiring board 1.

In the exemplary method illustrated in FIGS. 2 and 3, the spot facing portion 8 and the first opening part 5 are formed in the printed-wiring board 1 in this order. However, as opposed to the exemplary method of FIGS. 2 and 3, the first opening part 5 and the spot facing portion 8 are formed in the printed-wiring board 1 in this order.

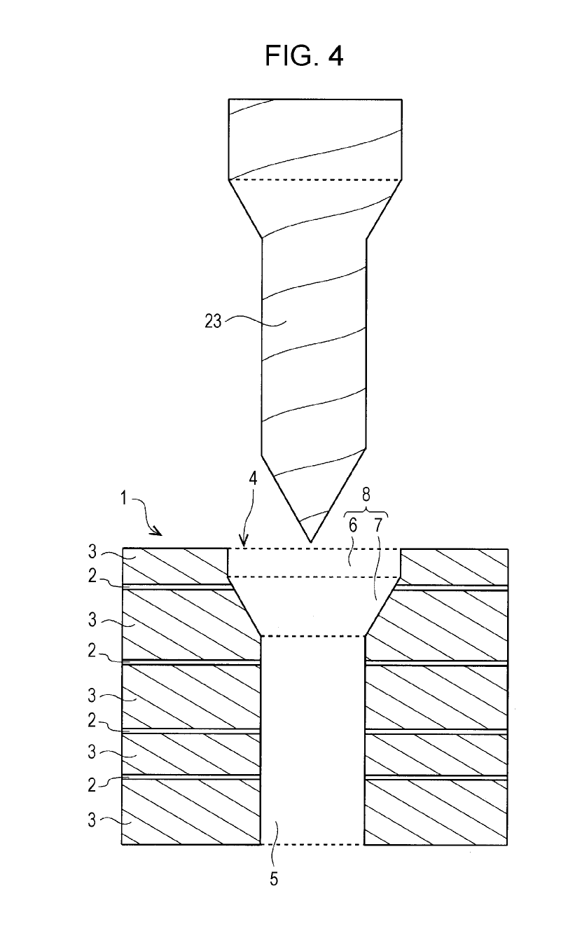

Alternatively, as illustrated in FIG. 4, the through-hole 4 may be formed in the printed-wiring board 1 by using a third drill (mechanical drill) 23. Specifically, the spot facing portion 8 and the first opening part 5 may be formed in the printed-wiring board 1 in the same process, with the third drill 23.

The third drill 23 has a first part, a second part, and a tapered part provided between the first and second parts. The second part has a larger diameter than the first part. The tapered part has a diameter that gradually decreases toward the first part from the second part. The third drill 23 drills into the printed-wiring board 1 with the tip of the third drill 23 oriented toward the first surface (lower surface), until the third drill 23 penetrates the printed-wiring board 1. As a result, the through-hole 4 is formed in the printed-wiring board 1.

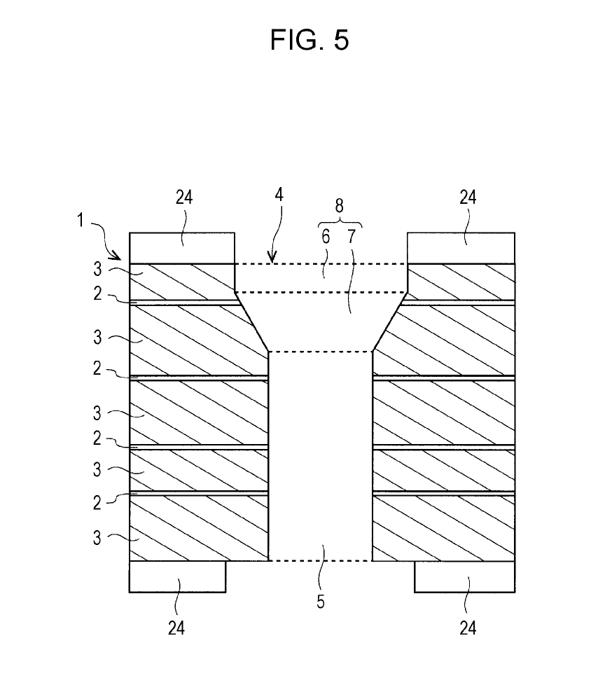

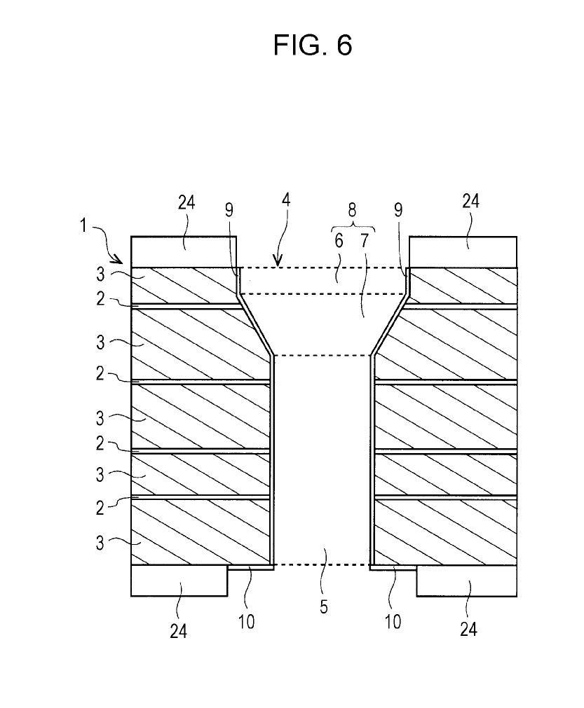

Then, as illustrated in FIG. 5, respective plating resist materials 24 are formed on the first surface (lower surface) and the second surface (upper surface) of the printed-wiring board 1. Subsequently, as illustrated in FIG. 6, the printed-wiring board 1 is subjected to an electroless or electrolytic plating process by using the plating resist materials 24 as masks. Through this process, a plating layer 9 is formed on the interior (or inner wall) of the through-hole 4, and a land 10 is formed on the first surface (lower surface) of the printed-wiring board 1.

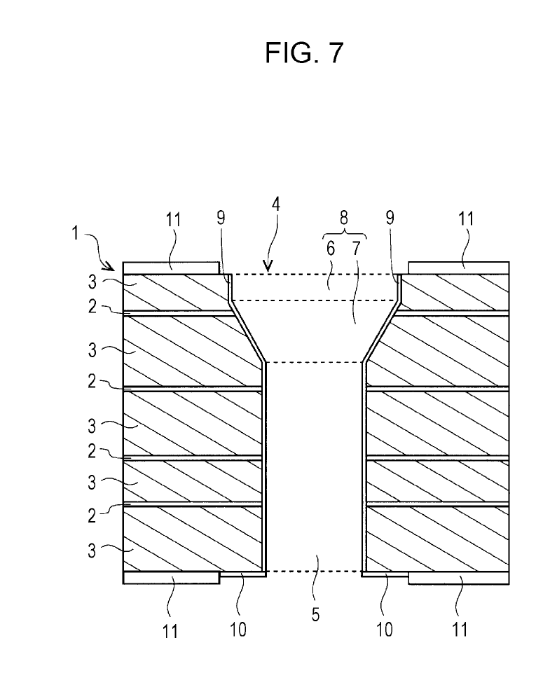

Finally, after the plating resist materials 24 are removed, respective solder resists 11 are formed on the first surface (lower surface) and the second surface (upper surface) of the printed-wiring board 1, as illustrated in FIG. 7. For example, the respective solder resists 11 may be formed on the first surface (lower surface) and second surface (upper surface) of the printed-wiring board 1 by applying the solder resists 11 to the first and second surfaces, and exposing and developing both surfaces.

### Example 1

### Method of Mounting Electronic Component 33

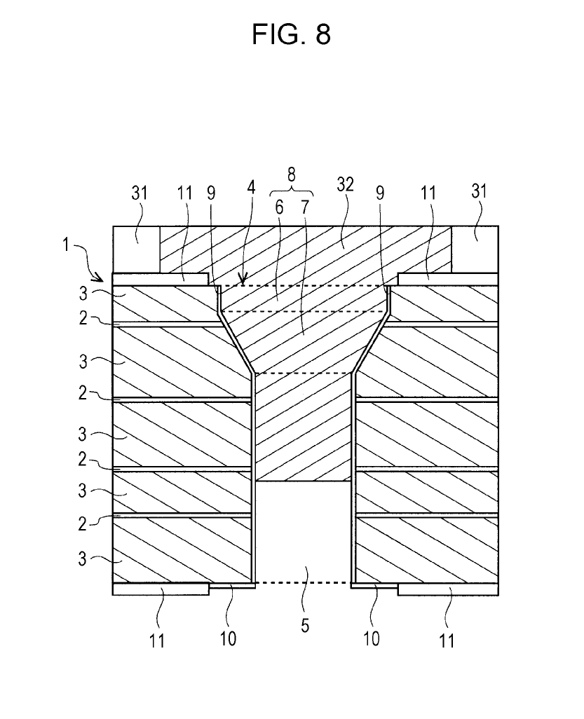

A description will be given of Example 1 of a method of mounting an electronic component 33 on the printed-wiring board 1 of FIG. 1, with reference to FIGS. 8 to 10. First, as illustrated in FIG. 8, a stencil mask 31 is formed on the second surface (upper surface) of the printed-wiring board 1, and subsequently, solder paste 32 is printed thereon. Through this processing, the solder paste 32 is applied to the interior of the through-hole 4 from the side of the second surface (upper surface) of the printed-wiring board 1. Specifically, the solder paste 32 is applied to the interior of the through-hole 4 through the second opening part 6. The stencil mask 31 is provided with openings at predetermined locations. The solder paste 32 is printed on the second surface (upper surface) of the printed-wiring board 1 by applying the solder paste 32 to the apertures of the stencil mask 31 with, for example, a squeegee. The solder paste 32 is a viscous material containing solder particles and flux. As illustrated in FIG. 8, the interior of the through-hole 4 is not entirely filled with the solder paste 32 at the time when the solder paste 32 is applied to the interior of the through-hole 4.

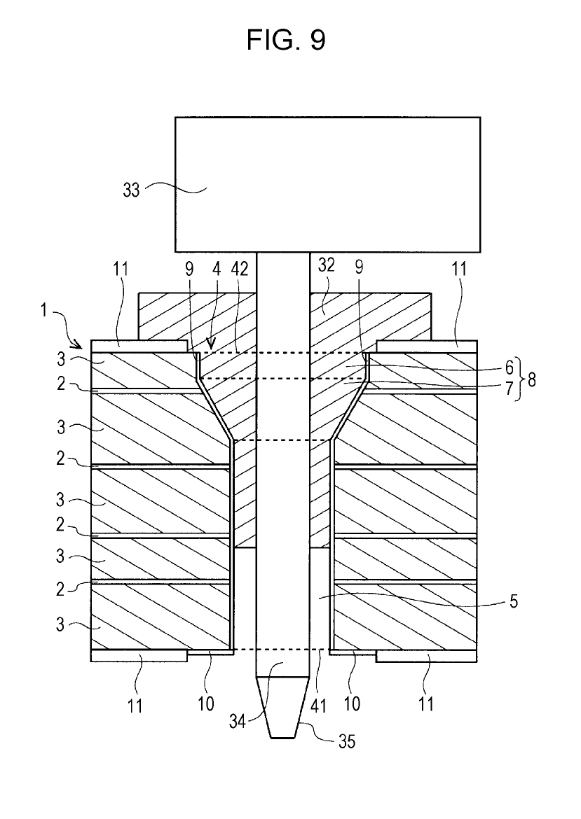

Then, as illustrated in FIG. 9, a lead pin 34 of an electronic component 33 is inserted into the through-hole 4 from the side of the second surface (upper surface) of the printed-wiring board 1, and the electronic component 33 is mounted on the second surface (upper surface) of the printed-wiring board 1. In other words, the lead pin 34 of the electronic component 33 is inserted into the through-hole 4 through the second opening part 6, and the electronic component 33 is mounted on the second surface (upper surface) of the printed-wiring board 1. The lead pin 34 of the electronic component 33, which is inserted into the through-hole 4, partially protrudes externally from the through-hole 4 through the aperture 41 at the first end of the through-hole 4. The lead pin 34 of the electronic component 33 is coated with a plating film 35 made of, for example, tin (Sn) or gold (Au). Herein, the plating film 35 is an example of a first plating film.

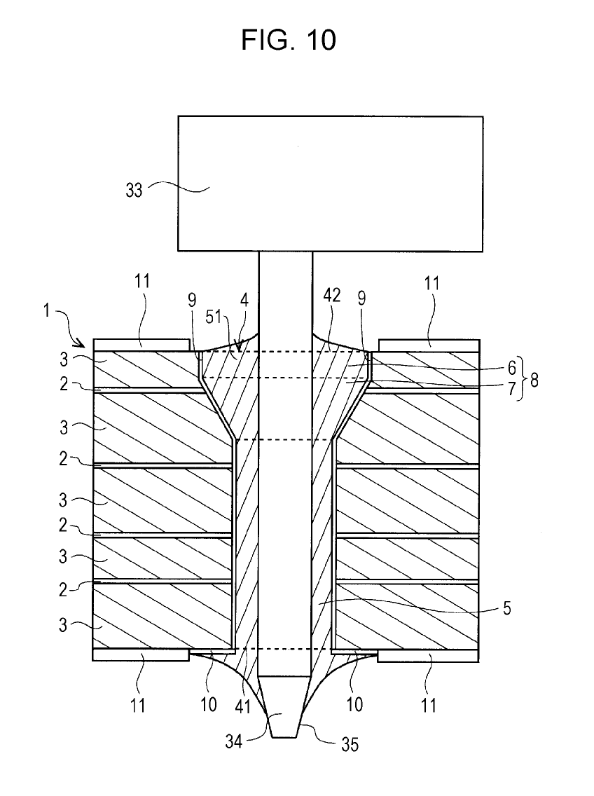

Then, with a reflow (heating) treatment, the interior of the through-hole 4 is entirely filled with solder 51, as illustrated in FIG. 10. During the reflow treatment, the solder particles in the solder paste 32 melt and agglutinate, and the flux therein evaporates. With the melting of the solder particles in the solder paste 32, the molten solder 51 flows down the through-hole 4, so that the interior of the through-hole 4 becomes entirely filled with the solder 51. Filling the through-hole 4 entirely with the solder 51 causes the lead pin 34 of the electronic component 33 to come into contact with the plating layer 9 in the through-hole 4. As a result, the electronic component 33 comes into physical contact with the printed-wiring board 1 while being electrically connected to the printed-wiring board 1.

The aperture 42 at the second end of the through-hole 4 has a larger diameter than the aperture 41 at the first end of the through-hole 4. This structure facilitates the entry of the solder paste 32 into the through-hole 4, thereby increasing the amount of the solder paste 32 in the through-hole 4. Specifically, this structure makes it possible to easily apply the solder paste 32 to the interior of the through-hole 4 through the spot facing portion 8, so that the application of the solder paste 32 in the through-hole 4 is increased. As a result of the increase in the amount of the solder paste 32 in the through-hole 4, the interior of the through-hole 4 is filled with an increased amount of solder 51, namely, the degree to which the interior of the through-hole 4 is filled with the solder 51 is increased.

Because the solder paste 32 is applied to the through-hole 4 more liberally, a larger amount of the solder paste 32 enters the through-hole 4, and thus the solder paste 32 is suppressed from spreading over the area surrounding the aperture 42 at the second end of the through-hole 4. For example, when the printed-wiring board 1 is thick, it is possible to increase the degree to which the thick printed-wiring board 1 is filled with the solder 51 by increasing the amount of the solder paste 32 applied to the through-hole 4.

The aperture 42 at the second end of the through-hole 4 has a larger diameter than the aperture 41 at the first end of the through-hole 4, as described above. This structure facilitates the insertion of the lead pin 34 of the electronic component 33 into the through-hole 4, which enables the electronic component 33 to be mounted on the printed-wiring board 1 easily. In addition, by not forming the land 10 around the aperture 42 at the second end of the through-hole 4, the land 10 is kept from coming off the surface of the printed-wiring board 1 due to the aggregation stress of the solder 51 contained in the solder paste 32 which is caused by the reflow treatment.

It is desirable for the depth of the spot facing portion 8 to be determined depending on the thickness of the printed-wiring board 1. As the depth of the spot facing portion 8 is increased, the amount of the solder paste 32 applied to the through-hole 4 is increased. For example, when the printed-wiring board 1 is thick, it is possible to increase the degree to which the interior of the through-hole 4 in the thick printed-wiring board 1 is filled with the solder 51 by increasing the depth of the spot facing portion 8. Furthermore, for example, when the thickness of the printed-wiring board 1 is significantly increased, it is possible to increase the degree to which the interior of the through-hole 4 in the thick printed-wiring board 1 is filled with the solder 51 by increasing both the amount of the solder paste 32 applied to the through-hole 4 and the depth of the spot facing portion 8.

### Example 2

### Method of Mounting Electronic Component 33

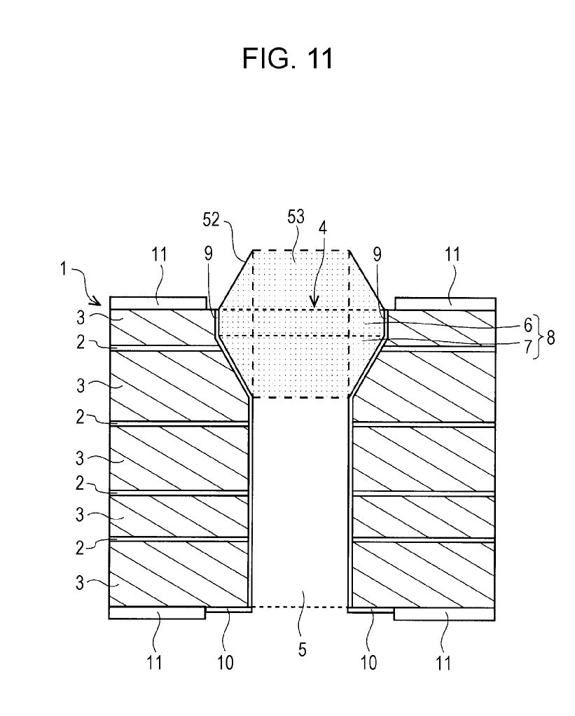

A description will be given of Example 2 of the method of mounting the electronic component 33 on the printed-wiring board 1 of FIG. 1, with reference to FIGS. 11 to 14. First, a solder ring 52 is set in the through-hole 4 in the printed-wiring board 1. As illustrated in FIG. 11, for example, the solder ring 52 may be set in a space defined by both the second opening part 6 and the third opening part 7. The solder ring 52 is provided with a through hole 53 which enables the lead pin 34 of the electronic component 33 to pass therethrough. It is desirable for the through hole 53 to have the same diameter as the first opening part 5 does. As illustrated in FIG. 11, the solder ring 52 is set in the space defined by both the second opening part 6 and the third opening part 7 while the outer surface of the solder ring 52 is in contact with the inner surfaces of the second opening part 6 and the third opening part 7. In this case, a plurality of solder rings 52 may be set in the space defined by both the second opening part 6 and the third opening part 7. For example, a first solder ring 52 and a second solder ring 52 may be set in the spaces defined by the second opening part 6 and the third opening part 7, respectively.

In FIG. 11, the solder ring 52 is formed in a shape whose upper part protrudes from the second surface (upper surface) of the printed-wiring board 1. However, there is no limitation on the shape of the solder ring 52. For example, the solder ring 52 may have a shape such that the solder ring 52 is entirely housed in the space defined by both the second opening part 6 and the third opening part 7. Alternatively, the solder ring 52 may have a shape such that the solder ring 52 is entirely housed in a space defined by the second opening part 6. In this case, the solder ring 52 may be set in the space defined only by the second opening part 6. Moreover, the solder ring 52 may be formed such that the solder ring 52 is entirely housed in a space defined by the second opening part 7. In this case, the solder ring 52 may be set in the space defined only by the second opening part 7.

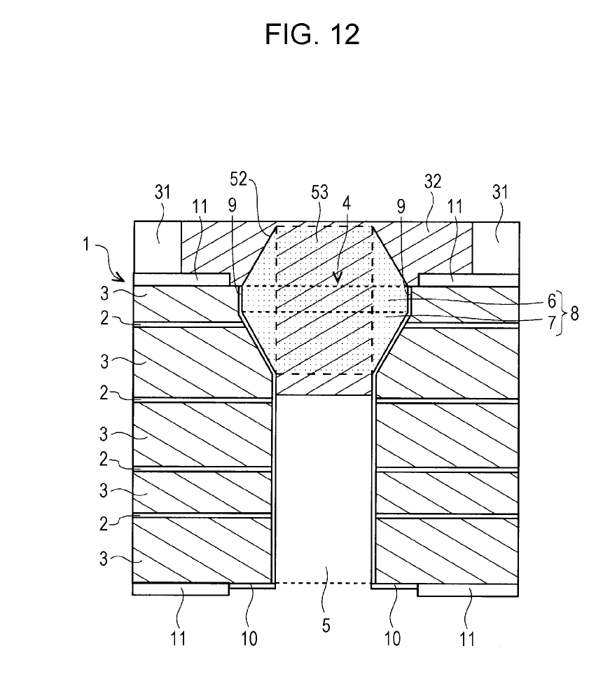

Then, as illustrated in FIG. 12, a stencil mask 31 is formed on the second surface (upper surface) of the printed-wiring board 1, and subsequently, a solder paste 32 is printed on the second surface (upper surface) of the printed-wiring board 1. With this process, the solder paste 32 is applied to the interior of the through-hole 4 from the side of the second surface (upper surface) of the printed-wiring board 1. In other words, the solder paste 32 is applied to the interior of the through-hole 4 through the second opening part 6. The solder paste 32 printed on the second surface (upper surface) of the printed-wiring board 1 is applied to the interior of the through-hole 4 through the through hole 53 of the solder ring 52. As illustrated in FIG. 12, the interior of the through-hole 4 is not entirely filled with the solder paste 32 at the time when the solder paste 32 is applied to the interior of the through-hole 4.

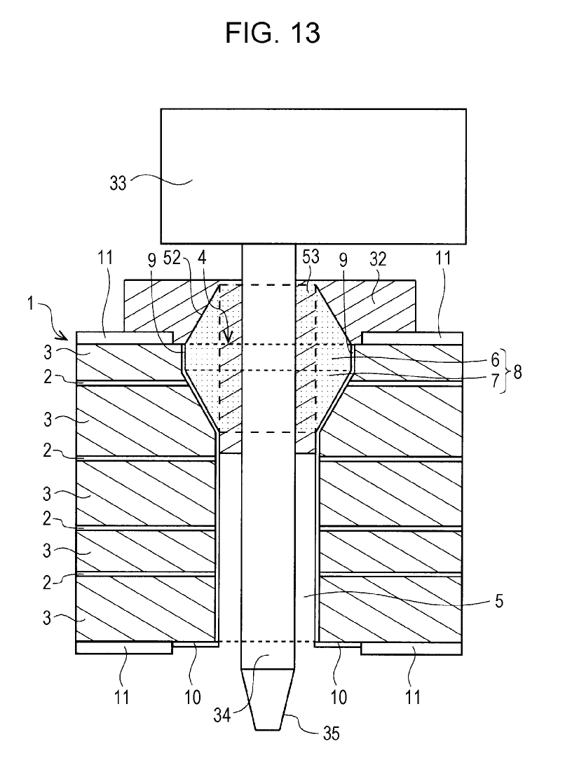

Then, as illustrated in FIG. 13, the lead pin 34 of the electronic component 33 is inserted into the through-hole 4 from the side of the second surface (upper surface) of the printed-wiring board 1, and the electronic component 33 is mounted on the second surface (upper surface) of the printed-wiring board 1. In other words, the lead pin 34 of the electronic component 33 is inserted into the through-hole 4 through the second opening part 6, and the electronic component 33 is mounted on the second surface (upper surface) of the printed-wiring board 1. In this case, the lead pin 34 of the electronic component 33 is inserted into the through-hole 4 through the through hole 53 of the solder ring 52. In addition, the lead pin 34 of the electronic component 33, which is inserted into the through-hole 4, partially protrudes outward from the aperture 41 at the first end of the through-hole 4.

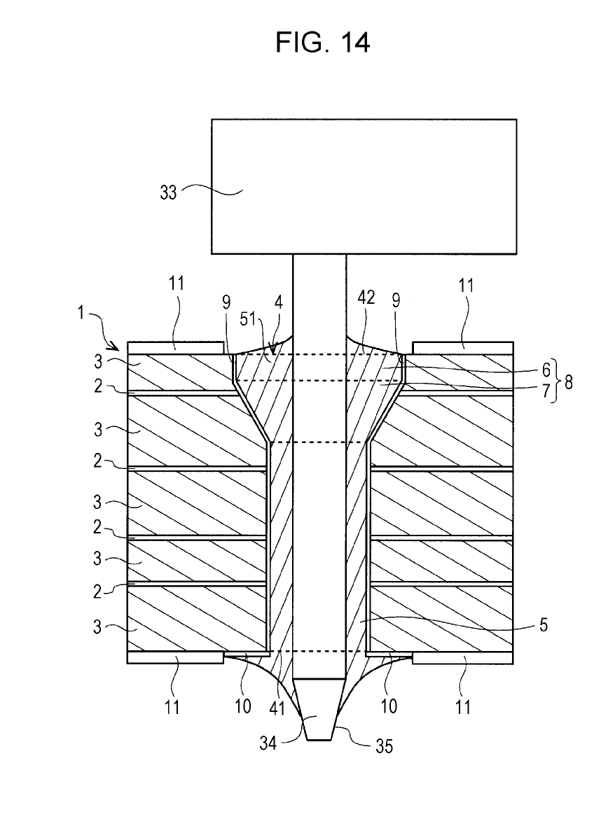

Then, as illustrated in FIG. 14, with a reflow (heating) treatment, the interior of the through-hole 4 is entirely filled with the solder 51. During the reflow treatment, the solder particles in the solder paste 32 melt and agglutinate, and the flux therein evaporates. Moreover, the solder ring 52 melts. With the melting of the solder particles in the solder paste 32 and the solder ring 52, the molten solder 51 flows down in the through-hole 4, so that the interior of the through-hole 4 is entirely filled with the solder 51. Filling the through-hole 4 with the solder 51 entirely causes the lead pin 34 of the electronic component 33 to come into contact with the plating layer 9 in the through-hole 4. As a result, the electronic component 33 comes into physical contact with the printed-wiring board 1 while being electrically connected to the printed-wiring board 1. With the solder ring 52 set in the through-hole 4, the amount of the solder 51 applied to the through-hole 4 is increased. In other words, the degree to which the interior of the through-hole 4 is filled with the solder 51 is increased.

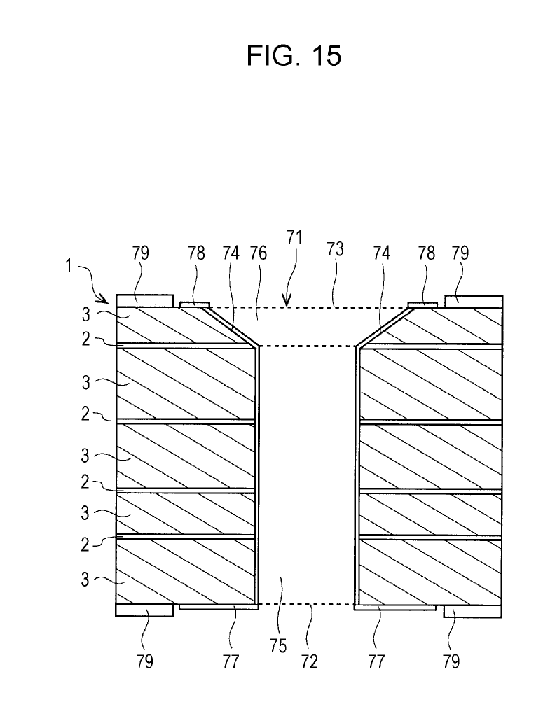

FIG. 15 is a view illustrating a cross section of a printed-wiring board 1 according to a comparative example. In FIG. 15, a through-hole 71 is formed so as to pass through the printed-wiring board 1. The through-hole 71 has an aperture 72 and an aperture 73 at respective ends, and the apertures 72 and 73 are provided on a lower surface and upper surface, respectively, of the printed-wiring board 1. The through-hole 71 has a plating layer 74 formed therein, and includes opening parts 75 and 76. The opening part 76 is formed in a tapered shape whose diameter gradually decreases toward the lower surface of the printed-wiring board 1 from the upper surface. A land 77 and a land 78 are formed on the lower surface and upper surface, respectively, of the printed-wiring board 1. The lands 77 and 78 are provided around the apertures 72 and 73, respectively, at both ends of the through-hole 71. In addition, solder resists 79 are formed on the lower surface and upper surface, respectively, of the printed-wiring board 1.

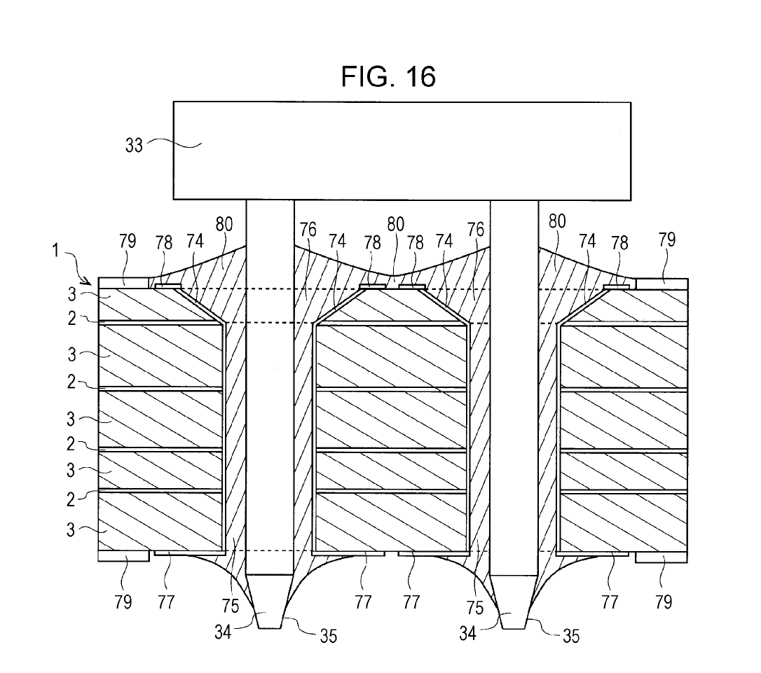

FIG. 16 is a view illustrating a cross section of the printed-wiring board 1 according to the comparative example in which adjacent through-holes 71 are arranged at a short pitch. When an electronic component 33 is mounted on the printed-wiring board 1 as illustrated in FIG. 16, respective portions of solder 80 around the adjacent through-holes 71 may be brought into contact with each other due to the short pitch between the adjacent through-holes 71.

In contrast, the printed-wiring board 1 according to the embodiment includes the spot facing portion 8 in each through-hole 4, and the plating film 9 formed on the inner wall of the spot facing portion 8. Further, no land 10 is formed around each aperture 42 at the second end of each through-hole 4. In this structure, the solder 51 is not formed around the aperture 42 at the second end of each through-hole 4. Thus, this structure keeps respective portions of the solder 51 filled in the adjacent through-holes 4 from being in contact with each other, even when the through-holes 4 are arranged at a short pitch. Consequently, with the printed-wiring board 1 according to the embodiment, no solder 51 is formed around the aperture 42 at the second end of each through-hole 4. It is therefore possible to make the pitch between the adjacent through-holes 4 be shorter than that of a printed-wiring board in which a land 10 is formed around an aperture 42 at a second end of each through-hole 4.

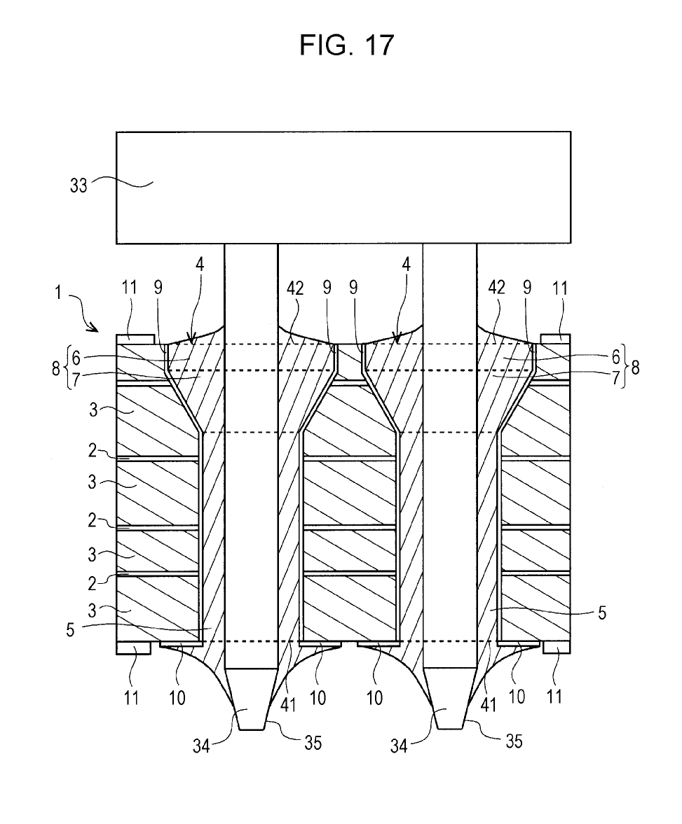

FIG. 17 is a view illustrating a cross section of the printed-wiring board 1 according to the example in which adjacent through-holes 4 are arranged at a short pitch. As illustrated in FIG. 17, because no land 10 is formed around the aperture 42 at the second end of each through-hole 4, respective portions of the solder 51 which are filled in the adjacent through-holes 4 are kept from being in contact with each other. With the printed-wiring board 1 according to the embodiment, even when the adjacent through-holes 4 and 4 are arranged at a short pitch, it is possible to keep respective joints of the solder 51 filled in the adjacent through-holes 4 from coming into contact with each other, and to increase the degree to which the interior of each through-hole 4 is filled with the solder 51.

### [Modification]

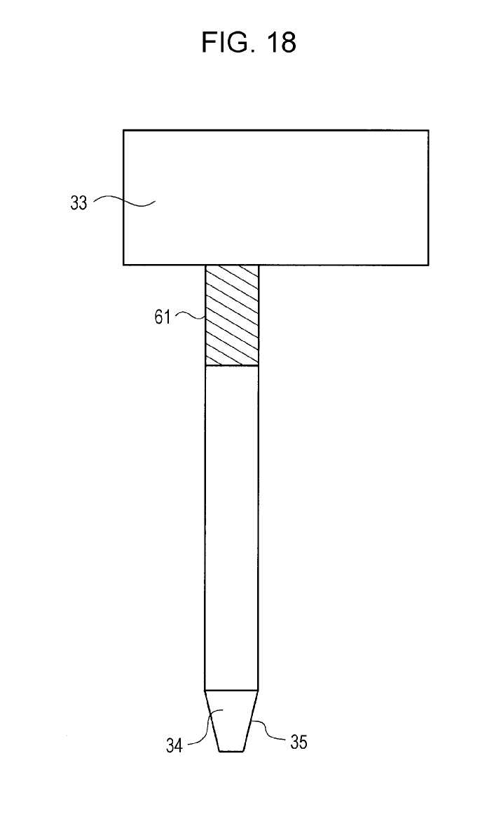

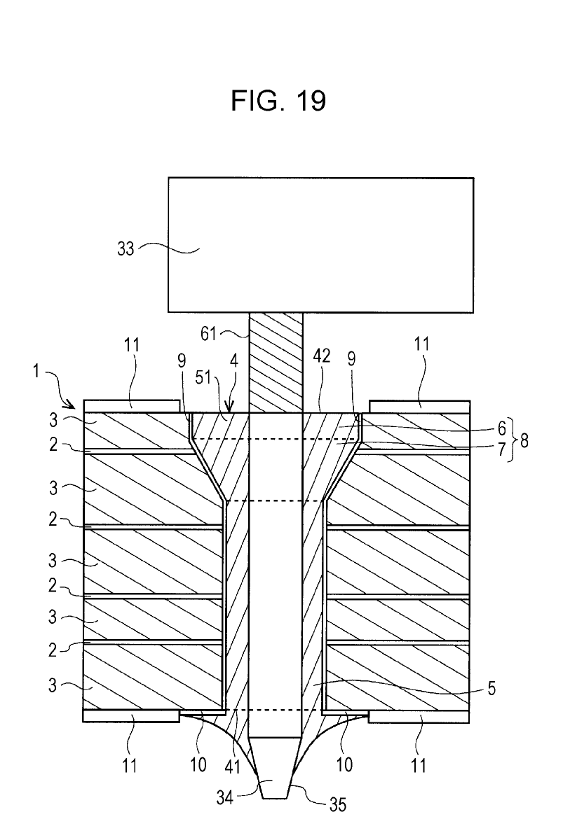

Next, a description will be given below, of a printed-wiring board 1 according to Modification of the embodiment, with reference to FIGS. 18 and 19. FIG. 18 is a view illustrating a side of the electronic component 33. In the electronic component 33 of FIG. 18, a part of the surface of the lead pin 34 is coated with the plating film 35 made of, for example, tin (Sn) or gold (Au), and another part thereof is coated with a plating film 61 made of, for example, nickel (Ni). Herein, the plating film 61 is an example of the second plating film. Hereinafter, the part of the lead pin 34 of the electronic component 33 which is coated with the plating film 35 is referred to as a “lower (or end) part”, whereas the part of the lead pin 34 which is coated with the plating film 61 is referred to as an “upper (or base) part.” Note that at the upper (or base) part of the lead pin 34 of the electronic component 33, the electronic component 33 and the lead pin 34 are connected to each other.

FIG. 19 is a view illustrating a cross section of the printed-wiring board 1 according to Modification of the embodiment. In FIG. 19, the lead pin 34 of the electronic component 33 is inserted into the through-hole 4 from the side of the second surface (upper surface) of the printed-wiring board 1, and the electronic component 33 is mounted on the second surface (upper surface) of the printed-wiring board 1. As illustrated in FIG. 19, the upper (or base) part of the lead pin 34 of the electronic component 33 protrudes from the second opening part 6. In this case, the plating film 61 exhibits worse wettability for the solder 51 than the plating film 35. Accordingly, during the reflow treatment, the solder 51 is kept from being formed around the upper (base) part of the lead pin 34 in the electronic component 33. Specifically, the molten solder 51 flows into the through-hole 4 readily during the reflow treatment, so that the interior of the through-hole 4 is filled with an increased amount of solder 51. Thus, in the electronic component 33 provided with the lead pin 34, a greater amount of the solder 51 is filled in the through-hole 4 than in that of an electronic component provided with a lead pin, the upper (or base) part of the surface of which is not coated with a plating film 61. Consequently, with the electronic component 33 provided with the lead pin 34, the degree to which the interior of the through-hole 4 is filled with the solder 51 is increased.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A method of fabricating a printed-wiring board comprising:
forming a through-hole across a thickness of a printed-wiring board, the forming of the through-hole including
forming a first opening part having a first diameter,
forming a second opening part having a second diameter, and
forming a third opening part provided between the first opening part and the second opening part,
wherein the second diameter is larger than the first diameter, and the third opening part is formed in a tapered shape whose diameter decreases toward the first opening part from the second opening part.

2. The method of fabricating a printed-wiring board according to claim 1, further comprising:
setting a solder ring provided with a through-hole in a space defined by the second opening part, a space defined by third opening part, or a space defined by both the second opening part and the third opening part;
applying solder paste to an interior of the through-hole from a side of the second opening part;
inserting a pin of an electronic component into the through-hole from the side of the second opening part; and
subjecting the printed-wiring board to a reflow treatment.

3. The method of fabricating a printed-wiring board according to claim 1, further comprising:
applying solder paste to an interior of the through-hole from a side of the second opening part;
inserting a pin of an electronic component into the through-hole from the side of the second opening part; and
subjecting the printed-wiring board to a reflow treatment.

4. The method of fabricating a printed-wiring board according to claim 2, wherein
a first plating film is formed on a part of a surface of the pin which is inserted into the through-hole,
a second plating film is formed on a part of the surface of the pin which protrudes from the second opening part; and
the second plating film exhibits worse solder wettability than the first plating film.

5. The method of fabricating a printed-wiring board according to claim 1, further comprising:
after the forming the through-hole,
forming a plating layer on an inner wall of the through-hole; and
forming a land on the printed-wiring board at a location in an area surrounding an aperture in the first opening part.

6. A printed-wiring board comprising:
a through-hole formed across a thickness of the printed-wiring board, the through-hole including
a first opening part having a first diameter,
a second opening part having a second diameter, the second diameter being larger than the first diameter, and
a third opening part provided between the first opening part and the second opening part, the third opening part being formed in a tapered shape whose diameter decreases toward the first opening part from the second opening part.

7. The printed-wiring board according to claim 6, further comprising an electronic component mounted on the printed-wiring board, wherein
a pin of the electronic component is inserted into the through-hole,
solder is filled in a space between the through-hole and the pin,
a first plating film is formed on a part of a surface of the pin which is inserted into the through-hole,
a second plating film is formed on a part of the surface of the pin which protrudes from the second opening part, and
the second plating film exhibits worse solder wettability than the first plating film.

8. The printed-wiring board according to claim 6, further comprising:
a plating layer formed on an inner wall of the through-hole; and
a land on the printed-wiring board at a location in an area surrounding an aperture in the first opening part.
